(19) United States
(12) Patent Application Publication
(10) Pub. No.: US 2004/0164772 A1
(43) Pub. Date: Aug. 26, 2004

(54) Device and method for frequency synthesis with high spectral purity

(76) Inventors: Pascal Gabet, Cholet (FR); Jean-Luc De Gouy, Briis Sous Forges (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/722,593

(22) Filed: Nov. 28, 2003

(30) Foreign Application Priority Data
Nov. 29, 2002 (FR) 02 15066

(51) Int. Cl. H03B 21/00

(52) U.S. Cl. 327/105

(57) ABSTRACT

A method and device is provided to synthesize a frequency F1→F2 with high spectral purity, the device entails a variable-step synthesizer F3→F4, which contains and least one variable-rank divider Nb located after the synthesizer and a frequency control device delivering the division rank command of the variable-rank divider, the command of the frequency of the variable-step synthesizer and the command of the synthesis step of the variable-step synthesizer.

### BACKGROUND OF THE INVENTION

1. Field of the Invention

The present invention relates to a device and method of synthesis with high spectral purity.

It relates especially to the variable division of a synthesizer with variable step size used to obtain high spectral purity and a constant frequency step size.

The schematic drawing of a phase-locked loop is given in FIG. 1. The loop comprises a voltage-controlled oscillator 1 (VCO) the phase of which has to be controlled in a feedback loop by a reference signal Fref. For this purpose, the output of the VCO is divided by a frequency divider 2 and the divided VCO is compared to the reference frequency Fref by means of a phase/frequency comparator 3. The error signal coming from the comparator is then filtered by the loop filter 4 which determines the stability of the feedback control loop. The VCO is controlled by a control voltage on which the filtered signal is superimposed. When the VCO is phase-controlled, the output frequency is equal to N*Fref where N is the rank of the divider. By making N vary from N1 to N2, (N2>N1) in steps of 1, the VCO swings by steps of a size equal to Fref in a frequency band corresponding to (N2-N1 )*Fref.

When it is sought to generate frequency steps smaller than Fref, it is possible to reduce the value of Fref but this has the consequence of augmenting the value of the division ranks and therefore of augmenting the phase noise of the synthesizer.

2. Description of the Prior Art

The technique known as the fractional step synthesis technique resolves this problem. It is illustrated in FIG. 2 in a block diagram of a 160-320 MHz synthesizer.

It consists in obtaining a dynamic variation in the N division rank so as to generate, for example, a mean value N comprising a fractional part. For example, if one out of ten times, the division is performed by N+1 instead of by N, the mean value N is equal to (N+1)/10. Since the rate of variation of N is far greater than the band of the feedback control loop, the VCO is offset by 1/10 of the frequency Fref. This results in a phase variation 2π/N at the phase/frequency comparator. This technique gives rise to parasitic lines at the output of the VCO. For a triple fractional step, which reduces the level of these parasitic lines, this variation goes to 6π/N.

This variation must be kept below 120° especially if the phase comparator used is a diode-based mixer type of phase comparator associated with a frequency-searching device. This is to the use of minimum division ranks equal to about 10.

The synthesizer has a VCO covering the 160-320 MHz frequency band. The VCO divided by N is compared with a reference frequency of 20 MHz. A control signal N/N+1/N+2 brings about variations, at a rate of 20 MHz, in the N division rank so as to generate steps at 100th of the value of the reference frequency (a double fractional step is used with modulo 2 equal to 4 and 25 so as to benefit from an additional attenuation on the first three fractional lines).

However, this method has major drawbacks:

1) The VCO must cover a one-octave band, and this means that it is difficult to make,

2) The N divider too covers one octave, inducing a variation by 2 in the feedback loop gain, and this variation gets combined with the possible variations of slopes of the VCO and leads to increased complexity, because these variations have to be compensated for in order to maintain the switching time and the level of the parasitic lines throughout the frequency range,

23) The switching time of the synthesizer is limited because the control loop band must be below the value of the first fractional line (200 KHz in the example given) to be able to benefit from an additional attenuation of this line through the transfer function of the phase loop,

4) Since the minimum division rank is close to 10 and since the divider must cover one octave, the result is an increase of at least 26 dB in the phase noise as compared with the technological noise of the dividers.

The invention relates to a method and a device that can be used especially to overcome the drawbacks of the prior art.

### SUMMARY OF THE INVENTION

The invention relates to a device to synthesize a frequency F1→F2 with high spectral purity, comprising a synthesizer with a variable step F3→F4. It is characterized by the fact that it comprises at least one variable rank divider Nb located after said synthesizer and a frequency control device delivering the division rank command of the variable rank divider, the command of the frequency of the variable-step synthesizer, the command of the synthesis step of the variable-step synthesizer.

The variable-step synthesizer is, for example, a fractional step phase-locked loop synthesizer.

The variable-rank divider Nb takes the values N1 to Np, these values following an arithmetic progression or a non-arithmetic progression.

The device may comprise a mixer receiving the output signal from the fractional step synthesizer and a mixing signal.

The invention also relates to a method to synthesize a frequency F1→F2 with high spectral purity using a variable-step synthesizer F3→F4. It is characterized by the fact that it comprises at least one step in which the output signal of the variable-step synthesizer is transmitted to a multiple-rank divider Np and by the fact that the division rank, the synthesis step of the synthesizer and the frequency of the variable-step synthesizer are modified.

The invention offers especially the following advantages:

it augments the performance of a fractional pitch synthesizer while being simple at the same time,

it provides remarkably gain by reducing the relative band of the VCO,

it improves spectral quality,

it increases the switching speed of the synthesizer

### BRIEF DESCRIPTION OF THE DRAWINGS

Other features and advantages of the invention shall appear more clearly from the following description of a detailed example given by way of a description that in no way restricts the scope of the invention, and from the appended drawings, of which:

FIG. 1 is a schematic drawing of the working of a fractional-step synthesizer,

FIG. 2 is a block diagram of a prior art fractional-step synthesizer,

FIG. 3 is a block diagram of an exemplary device according to the invention,

FIGS. 4 and 5 show alternative embodiments of the device of FIG. 3,

FIG. 6 shows a numerical example.

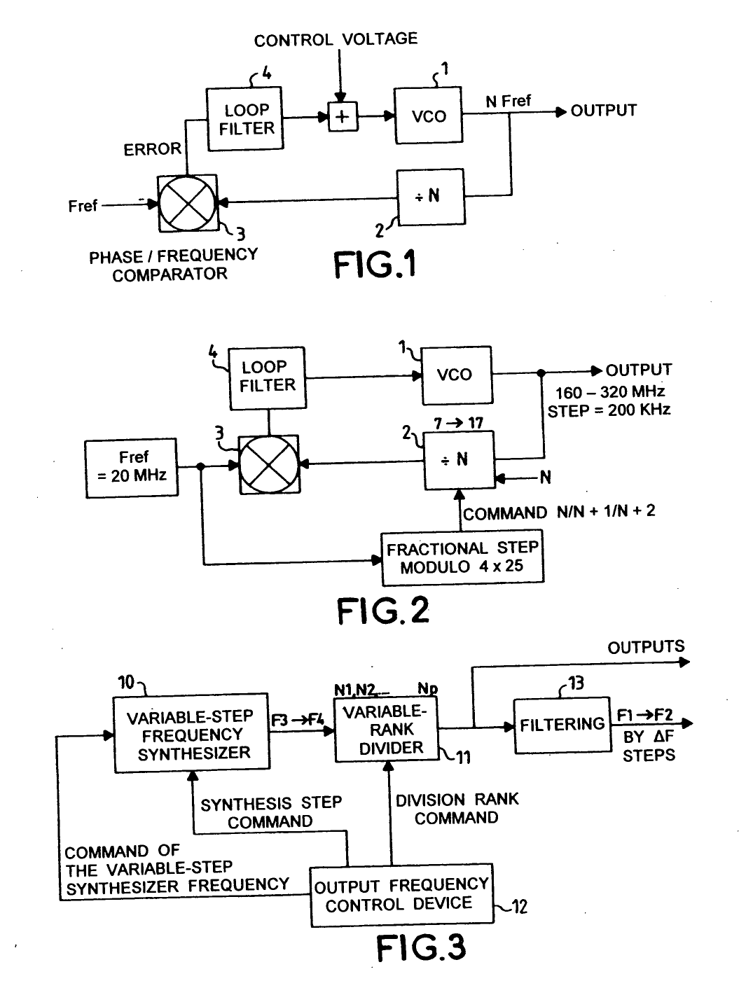

### MORE DETAILED DESCRIPTION

In order to provide for a clearer understanding of the object of the present invention, the following example, which is given by way of an illustration that in no way restricts the scope of the invention, relates to a 160-320 MHz frequency synthesizer.

The references given in FIGS. 2, 3, 4 and 5 designate similar elements.

FIG. 3 describes an exemplary device according to the invention, comprising, for example, a variable-step frequency synthesizer 10 that delivers a signal whose fundamental frequency ranges between a frequency F3 and a frequency F4. It comprises a variable-rank Nb divider 11 that assumes the values N1 to Np (with N1<N2 . . . <Np), a control device 12 to control the output frequency and, as the case may be, a filter 13.

The control device 12 delivers the following commands:

The command of the rank Nb of the variable-rank divider,

The command of the frequency of the variable-step synthesizer which varies from F3 to F4,

The command of the step of the variable-step frequency synthesis.

These three commands are, for example, implemented simultaneously in normal operation.

The smallest value of the division rank Nb is chosen for example to be equal to N1. This value N1 determines the desired improvement of the spectral qualities of the variable-step synthesizer in terms of phase noise and parasitic lines. The smallest value N1 is chosen for example as a function of the template of the phase noise desired at total output and the template of the phase noise possible for the synthesizer located upstream from the divider. Indeed, the fact, of dividing by the division rank Nb, whose smallest value is N1, will improve the phase noise of the variable-step synthesizer by at least 20 log(N1) dB.

The maximum frequency of the variable-step synthesizer is then given by F4=N1*F2, F2 being the maximum output frequency of the device according to the invention.

If the sequence N1 . . . Np is chosen in arithmetic progression, the minimum frequency of the variable-step synthesizer is given by N2. For example, F3 is chosen to be substantially equal to or slightly smaller than (N1/N2)*F4.

If the values of the sequence N1 . . . Np do not follow an arithmetic progression, the different ratios obtained are compared by dividing two consecutive elements of the sequence, that is N1/N2, N2/N3, . . . , (Np-1)/Np. In other words, a being the smallest value of these ratios, F3 is chosen for example to be substantially equal to a smaller than aF4 or the closest value or a value slightly below it.

Thus, the fact of varying the rank Nb of the divider enables the output band F1→F2 to be covered continuously so that there is only a relatively limited band synthesizer (F3→F4).

The different ratios N1/N2, N2/N3, . . . , (Np-1)/Np are not equal as a general rule. Hence, the frequency ranges obtained from F3→F4 in performing the divisions by N1, N2, . . . Np, namely F3/N1→F4/N1, F3/N2→F4/N2, . . . , F3/Np → F4/Np overlap each other partially; in other words, certain output frequencies may be obtained from two different division ranks Nb. In this case, to maximize the spectral performance of the device, the highest division rank Nb for example will be chosen.

To obtain the output frequency band F1→F2 with a constant frequency step ΔF, the method modifies the division rank Nb and also the synthesis step of the variable-step synthesizer. In other words:

when a division is made by N1, the synthesis step of the variable-step synthesizer must be N1ΔF,

when the division is made by N2, the synthesis step of the variable-step synthesizer must be N2ΔF, and so on and so forth.

Thus, the range of frequencies F1→F2 is covered with a constant frequency step ΔF.

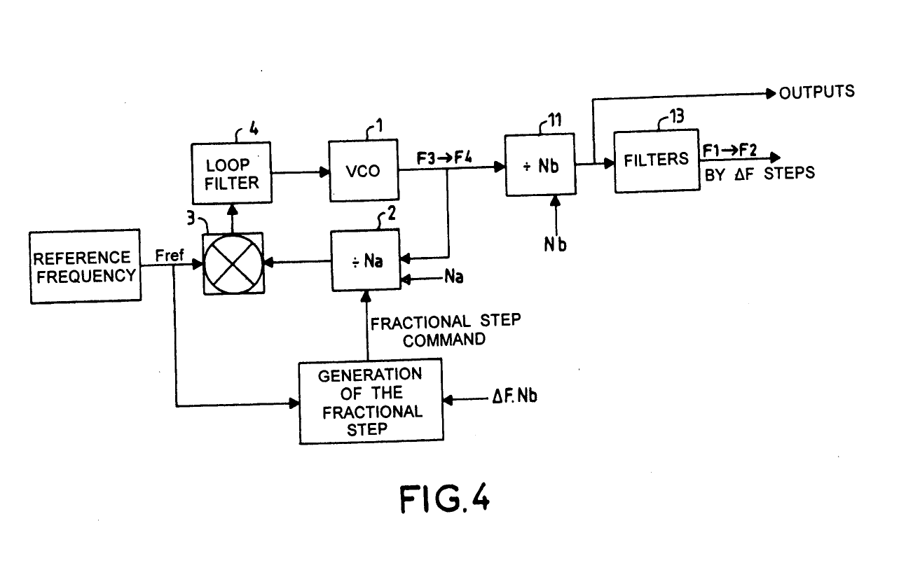

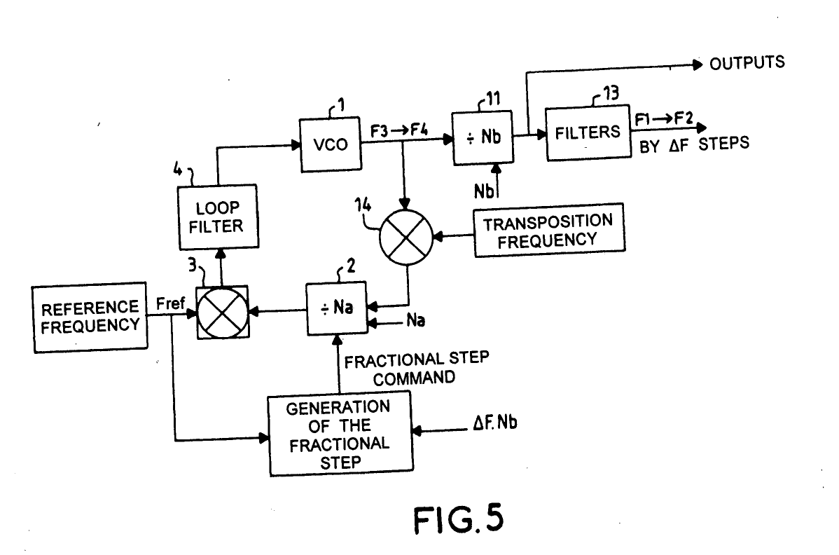

FIG. 4 shows an exemplary embodiment of the device according to the invention.

The device comprises a fractional synthesizer having an architecture that is substantially identical to the one given in FIG. 2 and shall not be described in detail, a variable divider 11 that divides by Nb, followed by optional filtering elements referenced 13. The variable-step synthesizer is formed, for example, by a fractional step phase-locked loop as described here above.

The fact of making this type of synthesizer work with variable step values is dictated by the need to obtain constant or substantially constant frequency steps values at output of the divider by Nb.

In a fractional step synthesizer, the frequency step is a fraction of the frequency Fref. For example, to obtain a step equal to Fref/5, the division rank Na of the frequency synthesizer is made to evolve over a cycle of 5 periods of Fref.

In the device according to the invention, the length of the cycle of evolution of Na is variable and dependent on the value Nb (division value of the variable-rank divider). The reference frequency Fref is chosen so that the desired fractional step values are obtained as follows:

Fref is a function of sequence of the values N1, N2, . . . Np that may be assumed by Nb,

Fref/ΔF must be a multiple of the LCM of N1, N2 . . . Np.

Thus, the numbers Fref/N1ΔF, Fref/N2ΔF, . . . , Fref/NpΔF are integers and define the different modulo values to be used for the fractional step in the respective cases where Nb is equal to N1, N2, . . . Np.

The term “modulo” is used because generally the fractional step is implemented by means of one or more accumulators for which the sum of the carry values commands the variations of the divider Na.

For example, with a reference frequency of 20 MHz, 200 KHz steps are obtained with a modulo 100 value, and this value can be decomposed into two accumulators modulo 4 and modulo 25 so as to obtain a double fractional step.

The device according to the invention uses either a simple fractional step or a multiple fractional step. To this end, the device comprises for example one accumulator or several accumulators which shall be programmable modulo so as to achieve the variable step values necessary for the method according to the invention.

It is clear that any device allowing to realize a cyclical command of the division rank Na, with the possibility of programming the length of the cycle, would be suitable.

FIG. 5 shows an alternative embodiment of the device of FIG. 4.

This variant consists in including a frequency transposition step in the fractional phase loop between the VCO and the divider Na. The transposition frequency is a multiple of ΔF multiplied by the LCM of the values of the division rank Nb. It is obtained by the addition, to the device, of the mixer 14 receiving the output signal from the VCO as well as the transposition frequency. The transposed signal is then transmitted to the divider 2.

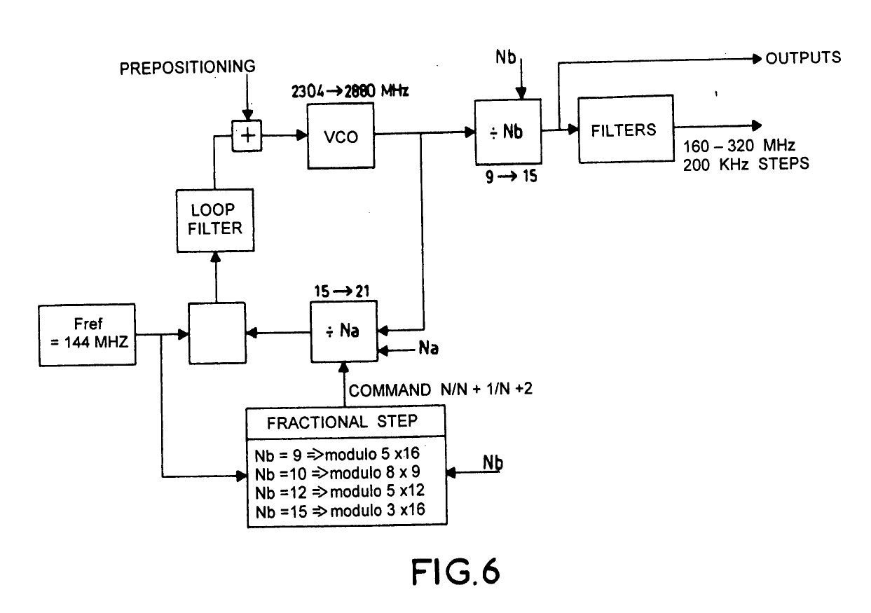

FIG. 6 illustrates a numerical example in which a device according to the invention is obtained with a 160-320 MHz frequency synthesizer.

In this example, Nb=9, 10, 12, 15, and the band of the VCO varies from 2304 to 2880 MHz to obtain the 160-320 MHz band in continuity.

To obtain a constant step size of 200 KHz at output, the fractional synthesizer must be capable of generating steps of 1.8 MHz, 2 MHz, 2.4 MHz, and 3 MHz.

The LCM of Nb is equal to 180. Fref should therefore be a multiple of 36 MHz.

A value of 144 MHz is chosen and the different modulo values to be obtained, namely 80, 72, 60 and 48, are deduced therefrom.

These modulo values may be decomposed into 2 for a double fractional step embodiment: 80=5×16, 72=8×9, 60=5×12, 48=3×16.

The following table 1 summarizes the performance obtained with a prior art synthesizer.

| CHARACTERISTIC | PERFORMANCE |
|---|---|
| Relative band of the VCO (B/Fo) | 67% |
| Increase of the noise relative to Fref + | +20 log (Nmax) = 26 dB |
| comparator noise | |
| Gain on the phase noise of the VCO | 0 dB |
| Frequency deviation of the parasitic line | 200 KHz |
| located at the boundary of the loop band | |
| Attenuation of the first parasitic line located | 58 dB @ 200 KHz |
| at the boundary of the loop band | |

Table 2 gives the results obtained with the new method and gives the gain on this example relative to the prior art.

| CHARACTERISTIC | PERFORMANCE | GAIN OVER THE PRIOR ART |
|---|---|---|
| Relative band of the | 22.2% | Relative band divided by 3 |
| VCO | | |
| Increase in noise | +20 log (Namax/Nbmin) = 6.94 dB | Gain of 19 dB on the phase |
| | | noise |
| Gain on the VCO noise | 20log(Nbmin) | Gain of 19 dB (limited by the |
| | | lower-limit phase noise of |
| | | Nb) |
| Frequency difference | 1.8 MHz => possibility of a | Gain by a ratio 9 on the |
| of the closest parasitic | wide loop band | switching speed |
| line | | |
| Attenuation of the first | 81 dB @ 1.8 MHz | Most efficient rejection of the |
| line located at the | | fractional lines + 23 dB on |
| boundary of the loop | | the first |

It can thus be seen that the proposed method is simple to implement and that it provides remarkable gain in terms of:

diminishing the relative band of the VCO,

improving the spectral quality

increasing the switching speed of the synthesizer

Without departing from the framework of the invention, any device that gives a variable step can be used. Such a device could be, for example, a fractional step synthesizer etc. or any other device known to those skilled in the art.

What is claimed is:

1. A device to synthesize a frequency F1→F2 with high spectral purity, comprising a synthesizer with a variable step F3→F4, comprising at least one variable rank divider Nb located after said synthesizer and a frequency control device delivering the division rank command of the variable rank divider, the command of the frequency of the variable-step synthesizer, the command of the synthesis step of the variable-step synthesizer.

2. A device according to claim 1 comprising a filtering device positioned after the variable-rank device Nb.

3. A device according to one of the claims 1 or 2, wherein the variable-step synthesizer is a fractional step phase-locked loop synthesizer.

4. A device according to one of the claims 1 or 2 wherein the variable-rank divider Nb takes the values N1 to Np, these values following an arithmetic progression, and wherein the maximum frequency of the synthesizer is given by F4=N1*F2 where N1 is the smallest value of the sequence and the frequency F3 is a function of N2.

5. A device according to claim 4 wherein the value of the frequency F3 is substantially equal to or slightly lower than (N1/N2)*F4.

6. A device according to one of the claims 1 or 2 wherein the variable-rank divider Nb takes the values N1 to Np, these values following a non-arithmetic progression.

7. A device according to claim 6 wherein F3 is substantially equal to or smaller than aF4 where a is the smallest value obtained in dividing two consecutive elements one after the other.

8. A device according to claim 6 wherein the highest division rank Nb is chosen.

9. A device according to claim 1 comprising a mixer receiving the output signal from the fractional step synthesizer and a mixing signal.

10. A method to synthesize a frequency F1→F2 with high spectral purity using a variable-step synthesizer F3→F4, comprising at least one step in which the output signal of the variable-step synthesizer is transmitted to a multiple-rank divider Np and wherein the division rank, the synthesis step of the synthesizer and the frequency of the variable-step synthesizer are modified.

11. A method according to claim 10 wherein the values Nb vary according to an arithmetic sequence N1 . . . Np and wherein the frequency F4 is determined by N1*F2 and the frequency F3 is a function of N2.

12. A method according to claim 11 wherein the value of the frequency F3 is chosen to be substantially equal to or slightly below (N1/N2)*F4.

13. A method according to claim 10 wherein the values Nb vary according to a non-arithmetic sequence and wherein two consecutive values of the sequence are divided.

14. A method according to claim 13 wherein F3 is substantially equal to or smaller than aF4 where a is the smallest value obtained in dividing two consecutive elements of the sequence.

15. A method according to claim 14 wherein the highest division rank Nb is chosen.

16. A method according to claim 10, wherein the modification of the commands of the divider and the variable-step synthesizer is simultaneous.

17. A method according to one of the above claims wherein the ratio of the reference frequency to the frequency step, Fref/ΔF, is the LCM of the sequence N1 . . . Np.
